(19) United States
(12) Patent Application Publication
(10) Pub. No.: US 2011/0014781 A1
(43) Pub. Date: Jan. 20, 2011

(54) METHOD OF FABRICATING SEMICONDUCTOR DEVICE

(76) Inventors: Hiroshi Itokawa, Olta-ken (JP); Ichiro Mizushima, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/837,025

(22) Filed: Jul. 15, 2010

(30) Foreign Application Priority Data
Jul. 16, 2009 (JP) P2009-168221

(51) Int. Cl. H01L 21/20

(52) U.S. Cl. 438/486; 257/E21.133

(57) ABSTRACT

According to one embodiment, a method of fabricating a semiconductor device includes forming a first insulator on a semiconductor substrate, forming a first groove on the insulator to expose at least a part of the semiconductor substrate at a bottom of the first groove, forming a first embedding film including at least germanium in the groove, melting the first embedding film by heat treatment, and crystallizing the first embedding film being melted to a single-crystalline film using the semiconductor substrate as a seed.

### CROSS REFERENCE TO RELATED APPLICATION

This application is based upon and claims the benefit of priority from prior Japanese Patent Application No. 2009-168221, filed on Jul. 16, 2009, the entire contents of which are incorporated herein by reference.

### FIELD

Embodiments described herein relate to generally a method of fabricating a semiconductor device having a columnar structure.

### BACKGROUND

LSI technology has been developed by scaling. However, LSI technology has been coming closer to limitation of scaling. Because fabricating processes of LSIs have become difficult with progress of scaling, and performances of LSIs are not necessarily conducted by miniaturization. One approach to overcome the limitation is that LSIs are to be fabricated as a three-dimensional structure.

As one method for forming the three-dimensional LSI, metal oxide semiconductor field effect transistors (MOSFET) which are conventionally formed in plane are vertically stacked on a surface of a semiconductor substrate. In other words, the LSI is formed perpendicularly to the surface of the semiconductor substrate, so that the LSI having high packing density can be realized without miniaturization in plane.

The semiconductor substrate with a single crystalline structure can be used as a channel in a MOSFET constructed on a surface of the semiconductor in parallel (called as a horizontally-structured MOSFET, hereafter).

On the other hand, a columnar structure constructed with single-crystalline silicon or germanium as the channel is essentially, when MOSFETs are stacked perpendicular to the surface of the semiconductor substrate (called as a vertically-structured MOSFET, hereafter).

For example, a method of single-crystalline silicon or germanium on an insulator in a planer structure is disclosed, for example as mentioned below.

Processing steps in fabricating method are mainly constituted with forming a silicon film or a germanium film on the insulator, thermally treating the film over melting point, and solidifying as the single-crystalline state in crystallization process at cooling down.

The method is effective for forming a MOSFET in plane. However, a layered structure having over two layers cannot be obtained by the method. Because, a silicon film, a germanium film or a silicon-germanium compound film is necessarily contacted with the surface of the single-crystalline silicon substrate.

Furthermore, the channel region of the MOSFET cannot be easily crystallized as a single crystal, when the columnar structure constructed with single-crystalline silicon or germanium is performed. For example, silicon or silicon-germanium is embedded in deep trench which is formed in an insulator on the semiconductor substrate. In this case, silicon or silicon-germanium is not constituted with a single-crystal but a poly-crystal.

Further, when the single-crystalline silicon is configured as a seed on the bottom portion of the deep trench, the seed cannot totally be crystallized as the single-crystal but only near contacted portion with the seed is crystallized as a single-crystal.

Further, the same method as disclosed in No.30p-E-2 of the fifty-sixth symposium on applied physics as mentioned above is employed, however, crystalline defects are generated as a problem in the columnar structure with high aspect ratio.

As mentioned above, the columnar structure with single-crystalline structure cannot be realized. Accordingly, difficult problems have been raised as a method of forming a vertically-structured MOSFET.

### BRIEF DESCRIPTION OF THE DRAWINGS

FIG. 1 is a perspective view schematically showing a semiconductor device according to a first embodiment of the present disclosure;

FIGS. 2A, 2B are cross-sectional views schematically showing processing steps in a method of fabricating the semiconductor device according to the first embodiment;

FIGS. 3A, 3B are cross-sectional views schematically showing the processing steps in the method of fabricating the semiconductor device according to the first embodiment;

FIG. 4 is a cross-sectional view schematically showing a semiconductor device according to a second embodiment of the present disclosure;

FIGS. 5A-5C are cross-sectional views schematically showing processing steps in a method of fabricating the semiconductor device according to a third embodiment of the present disclosure;

FIGS. 6A-6B are cross-sectional views schematically showing the processing steps in the method of fabricating the semiconductor device according to the third embodiment;

FIGS. 7A-7B are cross-sectional views schematically showing processing steps in a method of fabricating a semiconductor device according to a fourth embodiment of the present disclosure;

FIG. 8 is a cross-sectional view schematically showing the processing steps in the method of fabricating the semiconductor device according to the fourth embodiment;

FIG. 9 is a cross-sectional view schematically showing a semiconductor device according to a fifth embodiment of the present disclosure;

FIGS. 10A-10B are cross-sectional views schematically showing processing steps in a method of fabricating a semiconductor device according to a sixth embodiment of the present disclosure;

FIGS. 11A-11B are cross-sectional views schematically showing processing steps in a method of fabricating a semiconductor device according to a seventh embodiment of the present disclosure;

FIGS. 12A-12B are cross-sectional views schematically showing the processing steps in the method of fabricating the semiconductor device according to the seventh embodiment;

FIG. 13 is a cross-sectional view schematically showing the processing steps in the method of fabricating the semiconductor device according to the seventh embodiment;

FIG. 14 is a cross-sectional view schematically showing the processing steps in the method of fabricating the semiconductor device according to the seventh embodiment;

FIGS. 15A-15B are cross-sectional views schematically showing processing steps in a method of fabricating a semiconductor device according to an eighth embodiment of the present disclosure;

FIGS. 16A-16B are cross-sectional views schematically showing the processing steps in the method of fabricating the semiconductor device according to the eighth embodiment;

FIGS. 17A-17B are cross-sectional views schematically showing the processing steps in the method of fabricating the semiconductor device according to the eighth embodiment;

FIG. 18 is a cross-sectional view schematically showing a semiconductor device according to a ninth embodiment of the present disclosure;

FIG. 19A-19B are cross-sectional views schematically showing the semiconductor device according to the ninth embodiment;

FIG. 20 is a cross-sectional view as an explanation showing the semiconductor device according to the ninth embodiment.

### DETAILED DESCRIPTION

In general, according to one embodiment, a method of fabricating a semiconductor device includes forming a first insulator on a semiconductor substrate, forming a first groove on the insulator to expose at least a part of the semiconductor substrate at a bottom of the first groove, forming a first embedding film including at least germanium in the groove, melting the first embedding film by heat treatment, and crystallizing the first embedding film being melted to a single-crystalline film using the semiconductor substrate as a seed.

Embodiments will be described below in detail with reference to the attached drawings. Throughout the attached drawings, similar or same reference numerals show similar, equivalent or same components.

### First Embodiment

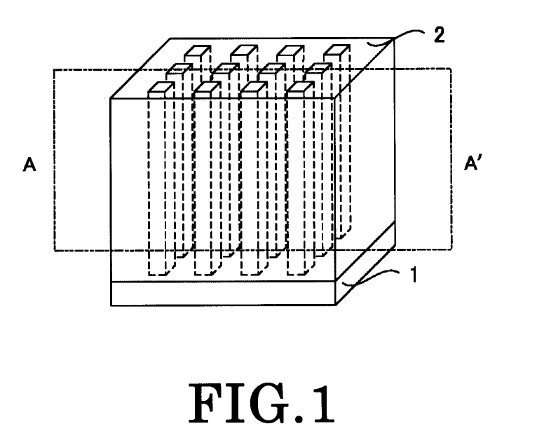

FIG. 1 is a perspective view schematically showing a semiconductor device according to a first embodiment of the present disclosure. A columnar structure constituted with a plurality of germanium films is formed in a SiO₂ film 2 on a single-crystalline silicon substrate 1.

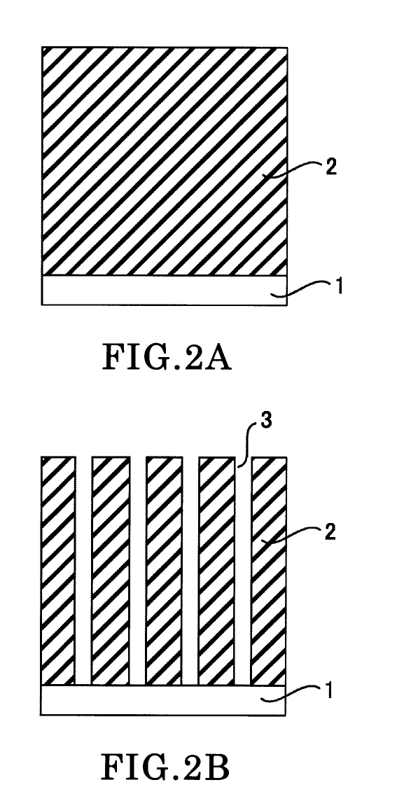

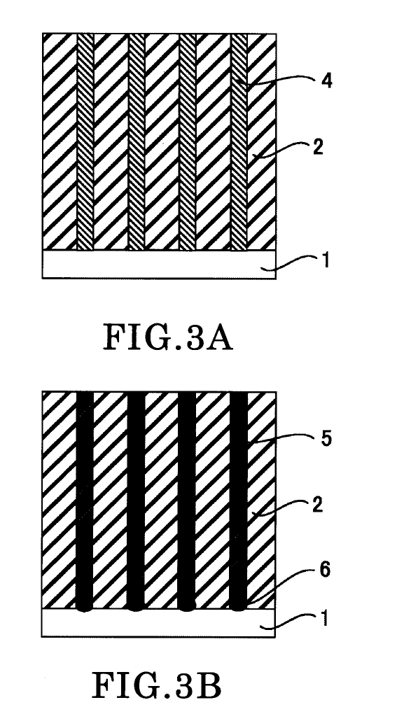

FIGS. 2A, 2B, 3A, 3B are cross-sectional views schematically showing processing steps in a method of fabricating the semiconductor device according to the first embodiment of the present disclosure. Hereafter, processing charts are represented by cross-sectional views cut at A-A′ plane in FIG. 1. The method of fabricating the semiconductor device is explained by using FIGS. 2A, 2B, 3A, 3B. First, the SiO₂ film 2 being insulator having a thickness of 5 μm is deposited on the single-crystalline silicon substrate 1 by using a conventional process, for example, CVD (Chemical Vapor Deposition) or the like, as shown in FIG. 2A. Subsequently, as shown in FIG. 2B, a plurality of grooves 3, each groove having a depth opened to a surface of the single-crystalline silicon substrate 1 in the SiO₂ film 2. A cross-sectional feature of each groove 3 is nearly square, further a side length of the square is set to be 25 nm.

In FIG. 2B, the cross-sectional feature of the groove 3 is showed to be nearly square, however, the feature may be a circle, for example. Specifically, single crystallization is attained as same as the above case when the groove 3 having a diameter of 5 nm is formed. When the diameter increases larger, the depth of the groove 3 may be below half of the diameter. For example, when the depth of groove 3 is set to be 1 μm, the diameter of the groove 3 may be below 500 nm. In addition, the diameter is corresponded to the diagonal length in the square case.

When the diameter of the groove 3 becomes far large to the depth of the groove 3, a ratio of a germanium amount in the groove 3 to an area contacting with the single-crystalline silicon substrate 1 having comparatively the higher melting point is larger. Consequently, many start points of the crystallization are formed when single crystallization is performed as mentioned below. Therefore, germanium in one groove being constituted with a single crystal can be difficult.

Successively, a germanium film 4 is deposited in the groove 3 and on the SiO₂ film 2 by using a conventional process or the like to be embedded in the groove 3 as shown in FIG. 3A. An unnecessary portion of the germanium film 4 on the SiO₂ film 2 is removed. Here, the germanium film 4 is deposited at a growth rate of 0.3 nm/min and a temperature of 400° C. by using GeH₄ gas as a source gas. The germanium film 4 is a poly-crystalline state after the deposition.

As shown in FIG. 3B, rapid thermal annealing (RTA) is performed in nitrogen ambient at a temperature of 980° C. for one second. The germanium film 4 is melted in the RTA process. Subsequently, the germanium film 4 is recrystallized in lowering the temperature. In the recrystallization, the germanium film 4 is grown from the single-crystalline silicon substrate 1 contacted at the bottom thereof as a seed to be formed as a single-crystalline germanium film 5. In the growth, a silicon-germanium compound region 6 (called as a Si—Ge compound region 6, hereafter) is formed near an interface region contacted between the silicon substrate 1 and the germanium film 4. The Si—Ge compound region 6 is contacted with the silicon substrate 1 at the bottom region and contacted with the single-crystalline germanium film 5 at the upper region. As the lattice constant of the Si—Ge compound is different with both the lattice constants of the silicon substrate land the germanium film 4, crystalline defects are included in the single-crystalline germanium film 5.

The RTA temperature is set to be 980° C. . However, necessity above 960° C. is revealed in an investigation of a temperature dependence on the crystallization state of the germanium film 4. Furthermore, a part of the germanium film 4 may be evaporated above 1300° C. RTA can be performed at least in the temperatures above the melting point of the germanium film 4 and less than the melting point of the single-crystalline silicon substrate 1.

The germanium film 4 can be formed above 400° C. in the deposition process. However, coverage of the germanium film 4 in the process is degraded above 550° C., so that voids may leave between the single-crystalline germanium film 5 and the groove 3 after the crystallization. Furthermore, the germanium film 4 can be formed below 400° C. to be obtained as an amorphous germanium film. However, the growth rate becomes lower, so that a practical utility is lowered to be raised as a problem. Therefore, the deposition temperature is desirable in the vicinity of 400° C.

### Second Embodiment

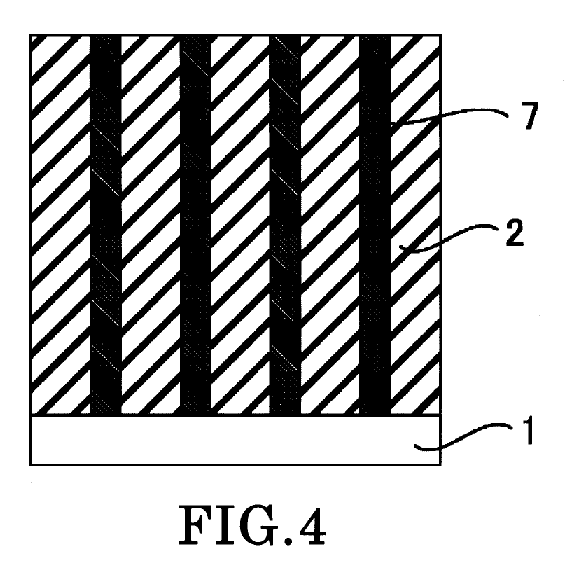

The germanium film 4 is used as a material embedded in the groove 3 in the first embodiment. However, a Si—Ge compound film including 20% of silicon as atomic ratio as shown in FIG. 4 in this embodiment instead of the germanium film. For example, monosilane (SiH₄), disilane (Si₂H₆) or the like can be used as a source gas of silicon.

A fabrication process is as the same as the fabrication process mentioned in the first embodiment other than a part of the fabrication process. Therefore, explanation in detail is omitted here. A Si—Ge film 7 is deposited in the groove 3 and on the SiO₂ film 2 to be embedded in the groove 3. Unnecessary Si—Ge film 7 on the SiO₂ film 2 is removed. Subsequently, heat treatment is performed at a temperature of 1045° C., for one second. A single-crystalline Si—Ge film 7 can be formed on the single-crystalline silicon substrate 1 by the heat treatment as the same as the first embodiment. The single-crystalline Si—Ge film 7 can inherit the crystalline property of the single-crystalline silicon substrate 1.

Further, silicon and germanium in the Si—Ge film can be formed with a stable eutectic state at any composition ratio. As the melting point of germanium and silicon are 938° C. and 1414° C., respectively, the melting point of the silicon and germanium is set to be temperatures between 938° C. and 1414° C. The melting point is increased with the silicon composition ratio. However, the processing step can be performed between above the melting point of the Si—Ge film and less than the melting point of the single-crystalline silicon substrate 1.

### Third Embodiment

The single-crystalline silicon substrate 1 is used as the seed of the all films in a crystallization process of the single-crystalline germanium film 5 and the single-crystalline Si—Ge film 7 in the first embodiment and the second embodiment. However, a seed is formed in each groove in this embodiment.

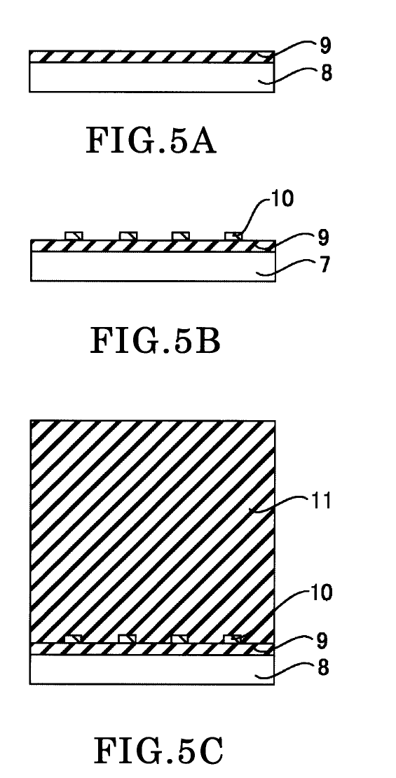

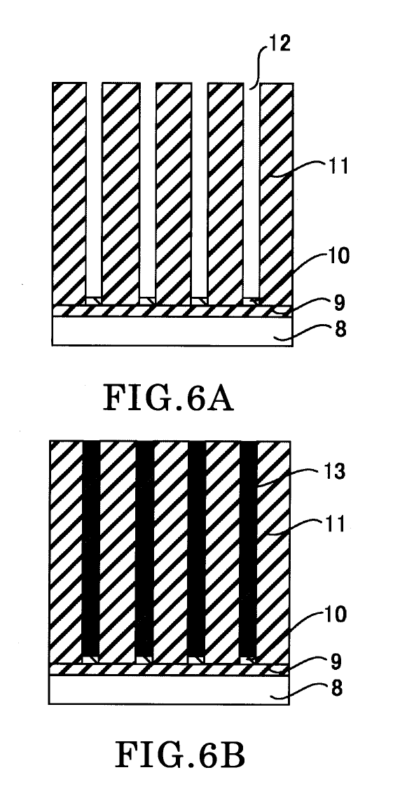

FIGS. 5A, 5B, 5C, 6A, 6B are cross-sectional views schematically showing processing steps in a method of fabricating the semiconductor device according to the third embodiment. The method of fabricating the semiconductor device is explained by using FIGS. 5A, 5B, 5C, 6A, 6B.

First, as shown in FIG. 5A, a SiO₂ film 9 is formed on a silicon substrate 8 by using thermal oxidation or the like, for example. Subsequently, a poly-crystalline silicon film 10 having a thickness of 5 nm is formed on the SiO₂ film 9 as shown in FIG. 5B. Successively, the poly-crystalline silicon film 10 is patterned by lithography or the like. In this embodiment, a plurality of the poly-crystalline silicon films 9 having an area of 25 nm square are formed by the patterning. Further, a lot of silicon islands can be fabricated by annealing silicon thin films. Anneal in deoxidizing ambient changes silicon thin films to silicon islands due to the migration of silicon. These islands, which are formed without lithography, can be used as seeds for crystallization.

As shown in FIG. 5C, a SiO₂ film 11 having a thickness of 5 μm is deposited on the SiO₂ film 9 and the patterned poly-crystalline silicon film 10 by CVD or the like. Subsequently, As shown in FIG. 6A, the SiO₂ film 11 is patterned by lithography or the like to form a plurality of grooves 12 on the SiO₂ film 11 by lithography or the like. In the process, a position and a shape of an opening of each groove 12 formed by patterning the SiO₂ film 11 is corresponded to the patterned poly-crystalline silicon film 9.

After forming the groove 12, a germanium film is deposited in the groove 12 and on the SiO₂ film 11 to be embedded in the groove 12. Un necessary germanium film on the SiO₂ film 11 is removed. Subsequently, heat treatment is performed at a temperature 975° C. for one second to form a single-crystalline germanium film 13 as shown in FIG. 6B. All the germanium films in the grooves are revealed to be crystallized as single crystals in investigating by transmission electron microscopy.

In this embodiment, a crystalline orientation of each of the single-crystalline germanium films 13 is different each other as different from the crystalline orientation of the first embodiment. This is because the crystalline orientation of the poly-crystalline silicon film 10 as the seed is at random due to the position, so that the single-crystalline germanium is crystallized by inheriting each crystalline property. Further, the poly-crystalline silicon film 10 is constituted with a plurality of crystals, however, the germanium film is crystallized as a single crystal. This is because a prescribed crystal in the poly-crystalline silicon film 10 becomes a base point to cause the crystallization.

The SiO₂ film 11 is patterned in the processing steps as shown in FIG. 6A in this embodiment to form the groove 12. It is not necessary for the position and the shape of the opening of the groove 12 to correspond to the poly-crystalline silicon film 1 patterned. When the pattern is intentionally shifted, forming the single-crystalline germanium film 13 is confirmed in a case that at least poly-crystalline silicon film 10 is exposed at a bottom of the groove 12. Further, when the pattern is shifted, an area of the poly-crystalline silicon film 10 exposed on the bottom of the groove 12 is decreased. In other words, the exposed area of the poly-crystalline silicon film 10 being the seed is decreased. Consequently, probability which more than two crystalline grains act as the seeds at a same time is decreased, the single-crystalline germanium film 13 having good crystalline property can be formed. Nearly a shift of 3 nm is proved to provide the effect mentioned above as compared to a pattern matching case.

The poly-crystalline silicon film 10 as the seed and the germanium film is used in this embodiment, respectively. However, the poly-crystalline Si—Ge film as the seed and the Si—Ge film as the material being embedded in the groove 12 may be used, respectively. In this case, at least crystallization of the embedded material only may start from the edge portion of the seed area. Namely, the melting point of the seed area may relatively be higher than the melting point of the embedded material. Specifically, a germanium concentration in the poly-crystalline Si—Ge film of the seed area may be lower than a germanium concentration in a Si—Ge film as the embedded material. When the concentration difference between the two Si—Ge films is over at least nearly 20%, the difference between the two melting points may be nearly 100° C. Accordingly, the method of fabricating the semiconductor device can be easily performed in this embodiment.

### Fourth Embodiment

The first embodiment, the second embodiment and the third embodiment also explains methods by one step on the formation of the groove and the deposition of the germanium film. However, it is difficult to form a groove by one step or a film in the groove with good coverage in a case of forming a columnar with a high aspect ratio.

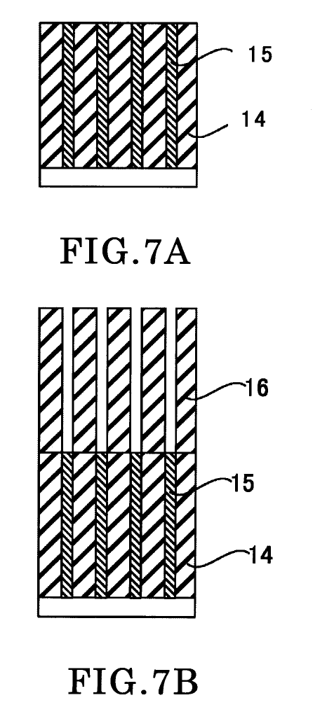

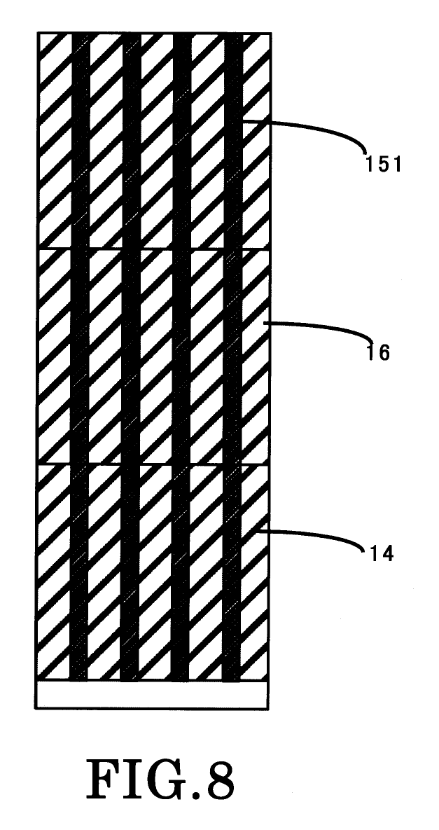

A groove and a film being embedded in the groove are formed by plural steps in this embodiment. As shown in FIG. 7A, a first layer of a SiO₂ film 14 and a germanium film 15 are formed by the same process as described in the first embodiment. However, crystallization of the germanium film 15 is not performed in this case. Subsequently, a second layer of a SiO₂ film 16 on the first layer of the SiO₂ film 14 and the germanium film 15 as shown in FIG. 7B. Successively, openings are formed in the second layer of the SiO₂ film 16. In this processing step, the opening in the SiO₂ film 16 may not correspond to the germanium film 15 by misalignment of a mask or the like. However, a problem is not caused because at least the germanium film 15 is exposed at the bottom of the SiO₂ film 16. A plurality of layers are stacked by repeating the processing steps to constitute a columnar structure with a high aspect ratio. Subsequently, heat treatment is performed by one step to easily crystallize the embedded material in the groove with the high aspect ratio after stacking all of the layers as shown in FIG. 8.

Further, the heating process may be desirable to be set as a condition which crystallization is generated from the bottom of the groove to obtain the single-crystalline germanium film with good crystalline property. Specifically, the wavelength of light for heating in the heating process is set to be shorter with the processing time, for example. Light can not attain at the lower layer by shortening the wavelength of light for heating, so that the crystallization can be generated from the bottom portion contacted with a seed. For example, the effect can be well utilized by combination with light having a wavelength of over 1 μm and light having a wavelength of below 1 μm. The former light can easily be through silicon, on the other hand, the later light is in difficulty through silicon.

### Fifth Embodiment

In the fourth embodiment, the embedded materials in the plurality of the stacked layers are the same composition material. However, a material of each layer has different composition each other in this embodiment.

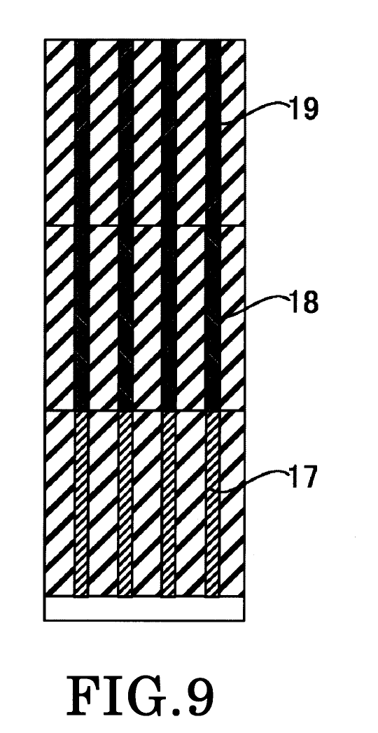

For example, as shown in FIG. 9, a first Si—Ge film 17 having a composition ratio as 50% of silicon and 50% of germanium is embedded in a groove of the lowest layer, a second Si—Ge film 18 having a composition ratio as 25% of silicon and 75% of germanium is embedded in a groove of a second layer, and a germanium film 19 is embedded in a groove of a third layer. In such a constitution, heat treatment is performed by one step to set a temperature which causes the embedded materials in all the layers as a melting state. In this embodiment, the temperature is set to be the melting point of the Si—Ge film 17 at the lowest layer. In such a manner, the films can be solidified from near the substrate in order in the crystallization. Accordingly, the crystallization of the embedded material is proceeded from the film near the substrate, so that the film crystallized without crystallization of other than a seed at halfway.

Further, the materials described in this embodiment are not restricted. The effect mentioned above can be obtained in a case where the melting point of the embedded material in the groove is lower from the lower layer to the upper layer. For example, carbon or the like which change the melting points of silicon, germanium, or Si—Ge can be doped to adopt the melting point of each film.

In this embodiment, the melting point of the embedded material in the groove is lower from the lower layer to upper layer as mentioned above. Consequently, the embedded material in the groove can be crystallized in each layer. As the crystallization temperature of a prescribed layer is selected at a temperature below melting point of the lower layer, the crystallization of the embedded materials in the groove are proceeded from the film near the substrate, so that the crystallization of the embedded materials in the groove with the high aspect ratio groove can easily performed.

### Sixth Embodiment

As mentioned in the first embodiment to the fifth embodiment, the germanium film or the Si—Ge film to be embedded in the groove are grown by single condition. On the other hand, an embedded material growth is performed by plural conditions in this embodiment.

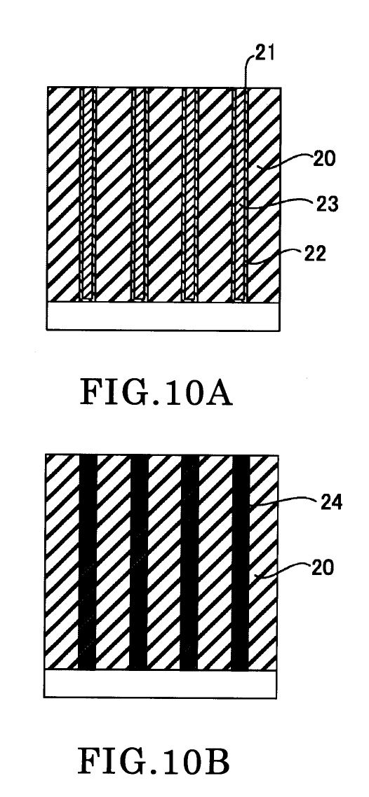

Specifically, a Si—Ge film 22 having a thickness of 3 nm is grown on an inside-wall of a groove 21 in a SiO₂ film 20 as a composition ratio of 50% germanium and 50% silicon as shown in FIG. 10A. Subsequently, a germanium film 23 is grown on the Si—Ge film 22 to be embedded in the groove 21. Successively, heat treatment is performed to melt the Si—Ge film 21 and the germanium film 23 in the groove 21, so that a single-crystalline Si—Ge film 24 with an uniform concentration is formed as shown in FIG. 10B. Here, uniformity means that elements constituting the Si—Ge film 22 and the germanium film 23 are uniformly distributed. Therefore, another element diffused from the silicon substrate is omitted.

Generally, flat growth of a germanium film having a higher concentration on an insulator is difficult. However, as described above, a film having comparatively lower germanium concentration is firstly grown. Successively, another film having comparatively higher germanium concentration is embedded in the groove 21, so that the film having comparatively higher germanium concentration is also easily formed in the groove 21. Further, the film having comparatively lower germanium concentration may be an amorphous silicon film or a poly-crystalline silicon film being constituted with silicon without germanium. This is because that sticking coefficient of germanium is lower than silicon on an insulator to easily form islands, however, silicon is easily adhered on an insulator to be obtained with a relatively flat growth in an initial stage. Accordingly, a silicon film growth without germanium in the initial stage can produce the most flat film so as to obtain more embedding characteristics of the groove. Further, monosilane or disilane is used as a source gas of silicon. In a comparison between monosilane and disilane as a viewpoint of the flat growth, disilane is desirable for a point of the flat growth on an insulator to adhere on the insulator. On the other hand, for a point of embedding characteristics, monosilane is desirable to be deposited in a deeper region of the groove in the same thickness. Further, higher silane such as tri-silane may be used to obtain thinner and more flat growth.

In this embodiment, a thickness or a composition of each film formed in the groove 21 is changed, so that a composition of the film is freely varied in the crystallization as the single-crystal.

### Seventh Embodiment

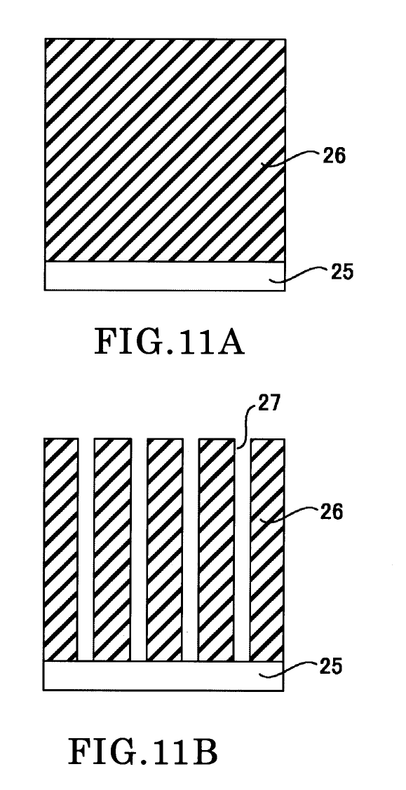

FIGS. 11A, 11B, 12A, 12B, 13 are cross-sectional views schematically showing processing steps in a method of fabricating the semiconductor device according to the seventh embodiment. The method of fabricating the semiconductor device is explained by using FIGS. 11A, 11B, 12A, 12B, 13. First, a SiO₂ film 26 being an insulator having a thickness of 5 μm is deposited on a single-crystalline silicon substrate 25 by using a conventional process, for example, CVD or the like, as shown in FIG. 11A. Subsequently, as shown in FIG. 11B, a plurality of grooves 27, each groove having a depth opened to a surface of the single-crystalline silicon substrate 25 in the SiO₂ film 26. A cross-sectional feature of each groove 27 is nearly square, and a side length of the square is set to be 25 nm.

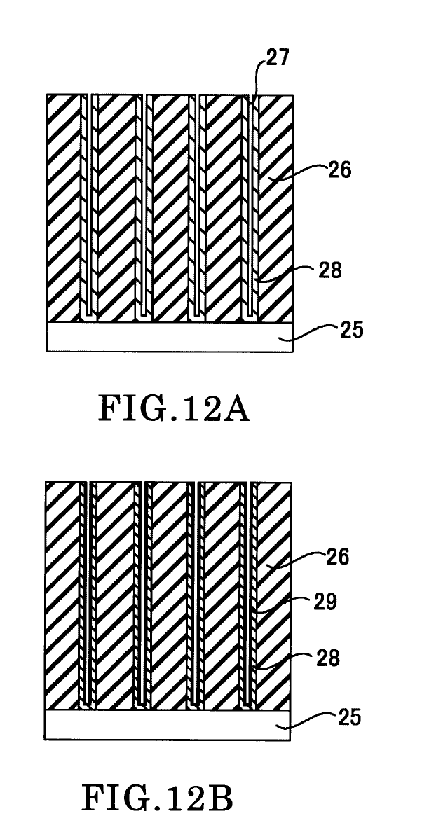

Successively, a Si—Ge film 28 with a germanium concentration of 30% is deposited in the groove 27 and on the SiO₂ film 26 as shown in FIG. 12A. The unnecessary Si—Ge film on the SiO₂ film 26 is removed. Here, the deposition of the Si—Ge film 28 is performed at a temperature of 500° C., a growth rate of 0.3 nm/min by using Si₂H₆ and GeH₄ as a source gas. As shown in FIG. 12A, heat treatment is performed in oxygen ambient at a temperature of 1025° C., for one minute to form a SiO₂ film 29a on a surface of the Si—Ge film 28. In this heat treatment in oxygen ambient, only silicon atoms in the Si—Ge film 28 is selectively oxidized, therefore, the germanium concentration of the un-oxidized portion in the Si—Ge film 28 is increased. In this embodiment, the germanium concentration is condensed to nearly 85%.

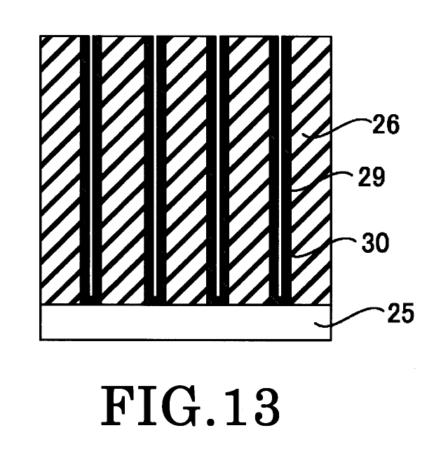

Next, heat treatment (RTA) in nitrogen ambient is performed at a temperature of 1050° C. for one second as shown in FIG. 13. In RTA, the Si—Ge film 28 is once melted. After melting, the Si—Ge film 28 is again crystallized with decreasing with the temperature. In this crystallization, the Si—Ge film 28 is grown as a single-crystalline Si—Ge film 30 aligned with crystalline property of the single-crystalline silicon substrate 25 in contact with the bottom thereof. Further, the SiO₂ film 29 formed on a surface of the Si—Ge film 28 has an effect for suppressing an agglomeration of the Si—Ge film 28 in heat treatment of the recrystallization process.

In the sixth embodiment mentioned before, flat growth of a film with a higher germanium concentration on the insulator is difficult. However, the film with a lower germanium concentration is firstly formed. Subsequently, the surface of the film with lower germanium concentration is oxidized as mentioned in this embodiment. As a result, the germanium concentration can be improved to be higher, so that the film having a higher germanium concentration can be formed in the groove with a high aspect ratio.

In this embodiment, an oxidation process and a melting process of the Si—Ge film 28 is performed, respectively. However, both processes may be performed as one oxidation process by controlling a temperature, heating time or the like. For example, in the process as shown in FIG. 12B, heat treatment is performed in oxygen ambient at a temperature of 1050° C. for one minute. The SiO₂ film 29 is formed and melting the Si—Ge film 28 starts when the germanium concentration rises up to nearly 80%. Subsequently, the single-crystalline Si—Ge film is grown by aligning with crystalline property of the single-crystalline silicon substrate 25 with decreasing the temperature of the oxygen heat treatment.

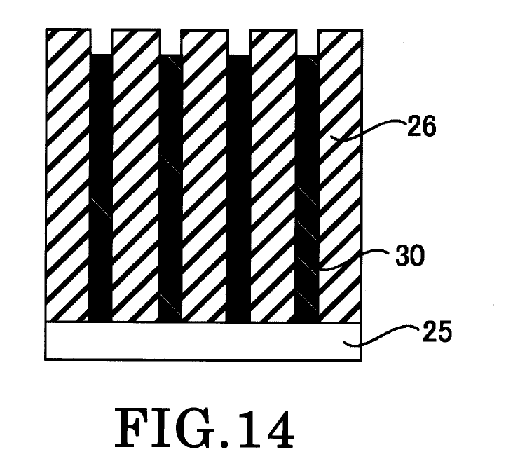

In this embodiment, melt crystallization is performed with leaving the SiO₂ film 29 by heat treatment. However, heat treatment may be performed to melt and to crystallize as a single-crystal after removing the SiO₂ film 29. In this case, the film flows to be embedded in a space of the groove 27 in the melt process as shown in FIG. 14, so that the crystallized single-crystalline Si—Ge film 30 becomes lower in height.

### Eighth Embodiment

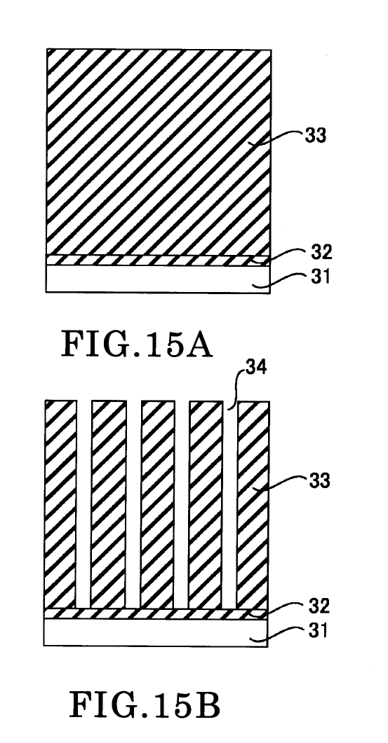

FIGS. 15A, 15B, 16A, 16B, 17A, 17B are cross-sectional views schematically showing processing steps in a method of fabricating the semiconductor device according to the eighth embodiment. The method of fabricating the semiconductor device is explained by using FIGS. 15A, 15B, 16A, 16B, 17A, 17B. In this embodiment, a single-crystalline germanium column is formed on an insulator as the same as the third embodiment mentioned above. However, this embodiment is different from the third embodiment in a point that a seed on the insulator is not formed.

As shown in FIG. 15A, a SiO₂ film 32 being an insulator of a lower layer is formed on a single-crystalline silicon substrate 31 by thermal oxidation, CVD or the like, for example. A SiO₂ film 33 having a 5 μm thickness is formed on the SiO₂ film 32 by CVD or the like, for example. Here, the first insulator as the lower layer may be different from the second insulator on the first insulator. As shown in FIG. 15B, the SiO₂ film 33 is patterned by lithography or the like to form a plurality of grooves 34 in the SiO₂ film 33. Each groove 34 is formed to expose a surface of the SiO₂ film 32 being the insulator of the lower layer.

Further, the SiO₂ film 33 may be directly formed on the single-crystalline silicon substrate 31 and a part of the SiO₂ film 33 may be leave on the bottom of the groove 34 by a selecting etching condition.

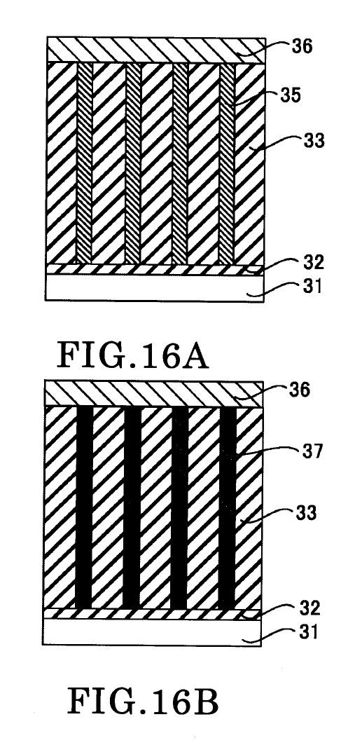

After forming the groove 34, a germanium film 35 is formed in the groove 34 of the SiO₂ film 33. The unnecessary germanium film on the SiO₂ film 33 is leaved, so that the germanium film 35 is embedded in the groove 34 as shown in FIG. 16A. Subsequently, a poly-crystalline silicon film 36 is deposited on the SiO₂ film 33 and the germanium film 35. Heat treatment 31 is performed at a temperature of 975° C. for one second to form a single-crystalline germanium film 37 on the silicon substrate as shown in FIG. 16B.

In this embodiment, a crystalline orientation of each single-crystalline germanium film 37 is different each other as the same as the third embodiment described before. This is because that the crystalline orientation of the poly-crystalline silicon film 36 as a seed is at random due to positions, so that each single-crystalline germanium is aligned to be crystallized. Further, the poly-crystalline silicon film 36 is constituted with plural crystal grains, however, the germanium film is crystallized as a single-crystal. This is because that a specific crystal grain in the poly-crystalline silicon film 36 acts as a starting point of the crystallization.

After forming the single-crystalline germanium film 37, a columnar of the single-crystalline germanium film 37 can be formed in the groove 34 by leaving the residual poly-crystalline silicon film 36. In this embodiment, the unnecessary germanium film on the SiO₂ film 33 is leaved, so that a contact area between the germanium film 35 and the poly-crystalline silicon film 36 is approximately suppressed to the opening area of the groove 34. Accordingly, the single-crystalline germanium film 37 can be formed in the groove 34.

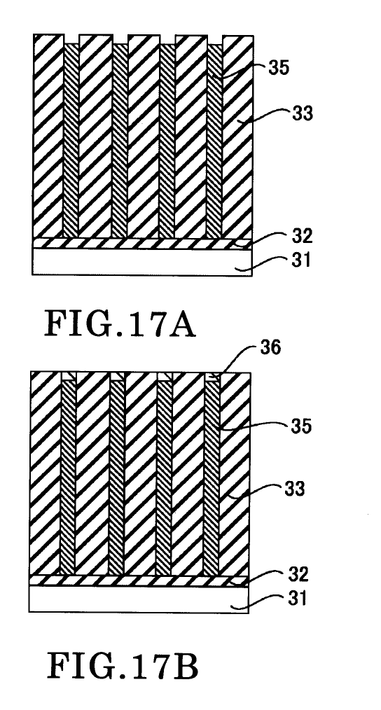

Further, as shown in FIG. 17A, a surface of the germanium film 35 may be etched in leaving the germanium film as shown in FIG. 16A. Successively, as shown in FIG. 17B, the poly-crystalline silicon film 36 is formed on the SiO₂ film 33 and the germanium film 35 and the poly-crystalline silicon film on the SiO₂ film 33 is removed.

In this structure mentioned above, the poly-crystalline silicon film 36 can move into the groove 34 accompanying with the melted germanium film 35, when the germanium film 35 is melted to flow into an inner void of the groove 34.

### Ninth Embodiment

In the embodiments from the first embodiment to the eighth embodiment, the feature of the groove is formed as a cylindrical prism, a square prism or the like to align with the same vertical direction in the insulator. In this embodiment, a cross section area of at least a part of the groove is smaller than a cross section area of an opening of an upper groove.

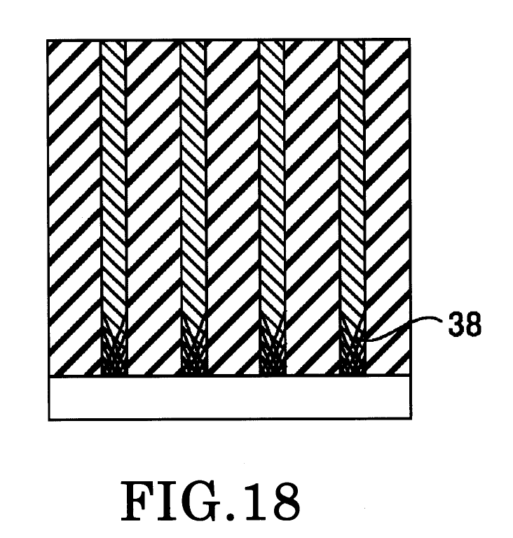

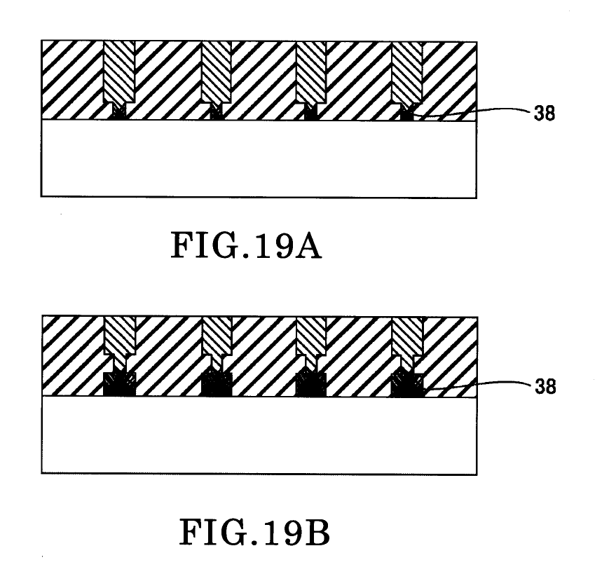

FIGS. 18, 19A, 19B are cross-sectional views schematically showing processing steps in a method of fabricating the semiconductor device according to the ninth embodiment. The method of fabricating the semiconductor device is explained by using FIGS. 18, 19A, 19B. In the embodiments from the first embodiment to the eighth embodiment, when the single-crystalline germanium film or the single-crystalline Si—Ge film is grown in the groove as shown in FIG. 2B, a Si—Ge region including defects is formed near the interface. As germanium or Si—Ge compound which has a larger lattice constant than a lattice constant of silicon is formed on a silicon film, many crystalline defects 38 may be generated from a seed portion as shown in FIG. 18.

Each crystalline defect 38 is generated due to a plane direction of the seed silicon crystal and is extended to a prescribed angle from a surface of the seed portion. It is obviously desire to suppress a generation region of the crystalline defect 38 to be smaller. In this embodiment, a region is formed in the groove where an area of the region is smaller than an area of an opening of an upper groove. As shown in FIG. 19A, for example, a lower opening area of the groove at the seed side is formed to be smaller than an upper opening area to form the same area region as the lower opening area to a prescribed height, so that the generation region of the crystalline defects 38 can be suppressed to be smaller.

Further, as shown in FIG. 19B, forming the region which has a smaller area than an area of the upper groove opening at the prescribed region in the groove can lead to suppress the generation of the crystalline defects above the prescribed region.

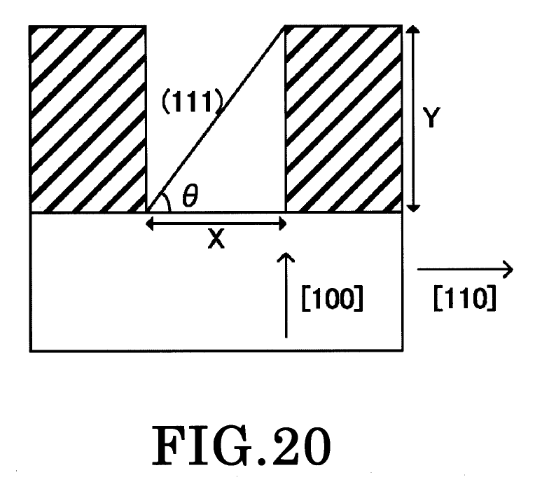

As shown in FIG. 20, when the lower opening area in the groove is smaller than the upper opening area in the groove, the angle between a crystalline defect plane and a surface of the silicon substrate is set to be θ and the diameter of lower opening in the groove is set to be X, and the height of the region with a narrow opening diameter is set to be Y. The generation region of the crystalline defects can be suppressed to be smaller by satisfying the formula 1 of Y<X×tan θ. For example, as shown in FIG. 20, an orientation of the crystalline defect plane is defined as (111) plane, the vertical direction to the silicon substrate plane is defined as [100] direction, the parallel direction to the silicon substrate plane is defined as [110] direction. As angle θ between the crystalline defect plane and the surface of the silicon substrate is 54.5 degrees, it is desirable to design X and Y to satisfy the formula 1.

Further, in the embodiments from the first embodiment to the eighth embodiment, the groove with an aspect ratio over 2 is defined as a columnar. In this embodiment, an aspect ratio is defined as a ratio between the height and the length of the short side in the bottom surface of the plane which is contacted with the single-crystal as the seed. This is because that the defect density to the uppermost of the columnar can be largely decreased by setting the aspect ratio over two. Namely, the upper region of the columnar can be constituted with a single-crystalline structure with less crystalline defects.

The aspect ratio over three can particularly diminish almost the defects attaining the uppermost portion. Further, the aspect ratio over four can restrict a region with defects to below intermediate portion in the columnar. Accordingly, aspect ratio over two can obtain at least a part of the single-crystalline columnar having high crystalline property.

While certain embodiments of the inventions have been described, these embodiments have been presented by way of example only, and are not intended to limit the scope of the inventions. Indeed, the novel methods and systems described herein maybe embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of fabricating a semiconductor device, comprising:
forming a first insulator on a semiconductor substrate;
forming a first groove on the insulator to expose at least a part of the semiconductor substrate at a bottom of the first groove;
forming a first embedding film including at least germanium in the groove;
melting the first embedding film by heat treatment; and
crystallizing the first embedding film to a single-crystalline film using the semiconductor substrate as a seed.

2. The method of claim 1, wherein
the heat treatment is performed between less than the melting point of the semiconductor substrate and above the melting point of the first embedding film.

3. The method of claim 1, wherein
the first embedding film is constituted with a silicon-germanium compound film.

4. The method of claim 1, wherein
the heat treatment is performed by light-irradiation, and light in the photo-irradiation are varied from longer wavelength to shorter wavelength.

5. The method of claim 3, wherein
forming the first embedding film includes forming a second embedding film and forming a third embedding film which has a higher germanium concentration than the second embedding film.

6. The method of claim 3, further comprising:
oxidizing the first embedding film after forming the first embedding film and before melting the first embedding film.

7. The method of claim 1, further comprising:
forming a second insulator on the first embedding film and the first insulator,
forming a groove in the second insulator to expose at least a part of the first embedding film,
forming a fourth embedding film including at least germanium in the groove of the second insulator,
melting the fourth embedding film with the first embedding film by the heat treatment,
crystallizing the fourth embedding film with the first embedding film to a single-crystalline film using the semiconductor substrate as the seed,
after forming the first embedding film.

8. The method of claim 7, wherein
melting the first embedding film and the fourth embedding film is performed after forming the fourth embedding film.

9. The method of claim 7, wherein
the heat treatment is performed by photo-irradiation, and light in the photo-irradiation are varied from longer wavelength to shorter wavelength.

10. The method of claim 7, wherein
the melting point of the first embedding film is higher than the melting point of the fourth embedding film.

11. A method of fabricating a semiconductor device, comprising:
forming a first insulator on a semiconductor substrate;
forming a seed layer on the first insulator;
forming the seed layer;
forming a second insulator on the seed layer and the first insulator;
forming a groove in the second insulator to expose at least a part of the seed layer at a bottom of the groove;
forming an embedding film including at least germanium in the groove;
melting the embedding film by heat treatment; and
crystallizing the embedding film being melted to a single-crystalline film using the seed layer.

12. The method of claim 11, wherein
the seed layer is a poly-crystalline silicon film.

13. A method of fabricating a semiconductor device, comprising:
forming an insulator on a semiconductor substrate;
forming a groove in the insulator;
forming an embedding film including at least germanium in the groove;
removing the embedding film on the insulator;
forming a seed layer on the embedding film after removing the embedding film on the insulator;
melting the embedding film after forming the seed layer;
crystallizing the embedding film being melted to a single-crystalline film using the seed layer.

14. The method of claim 13, wherein
a height of a surface of the embedding film is set to be lower than an opening of the groove in removing the embedding film on the insulator, and the seed layer is formed only in the groove in forming the seed layer.

15. The method of claim 13, wherein
at least a cross-section area of a part of the groove is smaller than an area of an upper opening of the groove.

16. The method of claim 13, wherein
the cross-section area of the groove is smaller than the area of the upper opening from a bottom to a prescribed height of the groove.
